(19) United States
(12) Patent Application Publication
(10) Pub. No.: US 2012/0298408 A1
(43) Pub. Date: Nov. 29, 2012

(54) SUBSTRATE FOR POWER MODULE AND POWER MODULE

(75) Inventors: Yoshiyuki Nagatomo, Saitama-shi (JP); Toshiyuki Nagase, Gotenba-shi (JP); Shinsuke Aoki, Gotenba-shi (JP)

(73) Assignee: Mitsubishi Materials Corporation, Chiyoda-ku (JP)

(21) Appl. No.: 13/576,940

(22) PCT Filed: Feb. 4, 2011
(86) PCT No.: PCT/JP2011/052428

§ 371 Date: Aug. 2, 2012

(30) Foreign Application Priority Data
Feb. 5, 2010 (JP) 2010-024705
Feb. 5, 2010 (JP) 2010-024706

(51) Int. Cl. H05K 1/18

(52) U.S. Cl. 174/260

(57) ABSTRACT

A substrate for a power module comprises a substrate main body having a plate-shape, a first surface, which is one surface of the substrate main body and a mounting surface that a semiconductor device is mounted on, and a second surface, which is the other surface of the substrate main body and an insulation layer is formed on, wherein the substrate main body is made of a metal matrix composite plate composed of a metal matrix composite in which metal is filled into a carbonaceous material.

### TECHNICAL FIELD

This invention relates to a substrate for a power module which is used in a semiconductor device for controlling, for example, a large electric current and a high voltage, and also relates to a power module.

The present application claims the right of priority to Japanese Patent Application No. 2010-024705 filed on Feb. 5, 2010 in Japan and Japanese Patent Application No. 2010-024706 filed on Feb. 5, 2010 in Japan, and the contents thereof are incorporated herein by reference.

### BACKGROUND ART

Among semiconductor devices, a power element for supplying electric power is relatively high in heating value. As a substrate for a power module which is mounted with a power element, for example, as described in Patent Documents 1 to 3, there has been proposed an insulation substrate in which a resin layer is formed as an insulation layer on a heat sink and a substrate main body composed of copper plate is placed on the resin layer. In this substrate for a power module, a semiconductor device (silicon chip) as a power element is mounted on the substrate main body via a soldering material.

In the above-described substrate for a power module, heat generated from the semiconductor device is spread in a plate-surface direction (a direction orthogonal to a laminated direction) on the substrate main body composed of a copper plate high in heat conductivity, and then, dissipated to the heat sink via the resin layer low in heat conductivity.

Here, heat-releasing characteristics of the insulation layer of the above-described substrate for a power module are expressed by heat resistance Rth shown below.

Rth=(1/k)×(t/S)

where

Rth is heat resistance,

k is heat conductivity,

t is a thickness of the insulation layer, and

S is an area of the insulation layer.

Further, for example, as shown in Patent Document 4, a substrate for a power module in which a metal plate of Al (aluminum) acting as a circuit layer (corresponding to a substrate main body) is bonded via an Al—Si based brazing material on one surface of a ceramic substrate (corresponding to an insulation layer) composed of MN (aluminum nitride) is widely used.

Moreover, a thermal expansion coefficient of silicon which constitutes a semiconductor device is approximately 2×10⁻⁶/° C. which is significantly different from a thermal expansion coefficient of copper or aluminum which constitutes the substrate main body. Therefore, where thermal cycle is imparted to a power module, stress resulting from a difference between the thermal expansion coefficients will affect a soldered layer, resulting in the possible occurrence of cracks in the soldered layer.

Recently, power modules have been made smaller and thinner, and they are now used under severe conditions. As a result, a heating value produced by electronic components such as semiconductor devices is increased to enlarge a difference in temperature of thermal cycle, and cracks tend to occur more easily on the above-described soldered layer.

It is conceivable that a substrate main body is constituted with a Cu—Mo alloy, by which a thermal expansion coefficient of the substrate main body is made approximate to a thermal expansion coefficient of a semiconductor device, thus suppressing the occurrence of cracks in the soldered layer.

However, the Cu—Mo alloy is decreased in heat conductivity to 170 W/m·K. Therefore, heat is not sufficiently spread to result in a failure of efficiently dissipating the heat generated from the semiconductor device.

The present invention has been made in view of the above situation, an object of which is to provide a substrate for a power module which is capable of efficiently dissipating heat generated from a semiconductor device and also suppressing the occurrence of cracks in a soldered layer set between the substrate for a power module and the semiconductor device even where thermal cycle is imparted and also to provide a power module which uses the substrate for a power module.

### PRIOR ART DOCUMENTS

### Patent Documents

Patent Document 1: Japanese Published Unexamined Patent Application No. 2007-142067
Patent Document 2: Japanese Published Unexamined Patent Application No. 2004-165281
Patent Document 3: Japanese Published Unexamined Patent Application No. 2006-114716
Patent Document 4: Japanese Published Unexamined Patent Application No. 2005-219775

### SUMMARY OF THE INVENTION

### Means for Solving the Problem

The substrate for a power module of the present invention is a substrate for a power module comprising a substrate main body having a plate-shape, a first surface, which is a surface of the substrate main body and is a mounting surface that a semiconductor device is mounted on, and a second surface, which is another surface of the substrate main body and an insulation layer is formed thereon. In addition, the substrate main body is made of a metal matrix composite plate composed of a metal matrix composite in which metal is filled into a carbonaceous material.

In the above-described substrate for a power module, a thermal expansion coefficient of the substrate main body can be set smaller than a thermal expansion coefficient of a metal such as copper. It is, therefore, possible to suppress the occurrence of cracks in a soldered layer resulting from thermal cycle.

In a first aspect of the substrate for a power module of the present invention, the metal matrix composite plate has anisotropy so that heat conductivity in one direction is higher than heat conductivity in the other directions, and the higher-heat conductivity direction of the substrate main body is oriented to a thickness direction of the substrate main body.

In the above-described substrate for a power module, even where the substrate main body is made greater in thickness, heat can be transmitted to the thickness direction. Therefore, it is possible to accelerate diffusion of heat in the plate-surface direction and to spread and dissipate heat generated from the semiconductor device on the substrate main body by making the substrate main body greater in thickness.

In the first aspect of the substrate for a power module of the present invention, it is acceptable that a relationship between thickness ts (mm) of the substrate main body, an area S (mm²) of the substrate main body and a junction area S₀ (mm²) of the semiconductor device satisfies a formula, 0.003≦ts/(S−S₀)≦0.015.

In the above-described substrate for a power module, with respect to the area S of the substrate main body, the thickness ts thereof can be secured to spread heat entirely over the area S of the substrate main body. Further, the thickness of the substrate main body is not made thicker than necessary, and the heat can be transmitted efficiently in the thickness direction.

In a second aspect of the substrate for a power module of the present invention, the substrate main body is made of a plurality of laminated metal matrix composite plates composed of a metal matrix composite in which metal is filled into the carbonaceous material. The metal matrix composite has anisotropy so that heat conductivity in one direction is higher than the heat conductivity in the other directions. A higher-heat conductivity direction of one of the metal matrix composite plates is different from the higher-heat conductivity direction of the other metal matrix composite plates of the substrate main body.

In the above-described substrate for a power module, the heat generated from the semiconductor device is dissipated preferentially in a mutually different direction on each of the metal matrix composite plates of the substrate main body. It is, thus, possible to efficiently dissipate the heat. One metal matrix composite plate and the other metal matrix composite plate are adjusted for the thickness, thus making it possible to adjust a direction in which the heat is dissipated.

In the second aspect of the substrate for a power module of the present invention, it is acceptable that, the higher-heat conductivity direction of the one of the metal matrix composite plates is oriented to the thickness direction of the substrate main body in the substrate main body.

In the above-described substrate for a power module, the higher-heat conductivity direction of the one of the metal matrix composite plate is oriented to the thickness direction of the substrate main body (that is, a direction in which the substrate main body and the heat sink are laminated). Therefore, the higher-heat conductivity direction of the other metal matrix composite plates is oriented to a direction other than the thickness direction. It is, thus, possible to spread and dissipate heat on the other metal matrix composite plate. Further, since the higher-heat conductivity direction of one of the metal matrix composite plate is oriented to the thickness direction of the substrate main body (the laminated direction), it is possible to dissipate the heat generated from the semiconductor device to the heat sink preferentially.

In the second aspect of the substrate for a power module of the present invention, it is acceptable that, the substrate main body is laminated by three metal matrix composite plates, and a higher-heat conductivity direction of a first metal matrix composite plate, a higher-heat conductivity direction of a second metal matrix composite plate, and a higher-heat conductivity direction of a third metal matrix composite plate are orthogonal to each other.

In the above-described substrate for a power module, it is possible to scatter and dissipate heat in three directions.

In the second aspect of the substrate for a power module of the present invention, it is acceptable that the thickness of the first, the second, and the third metal matrix composite plates are the same.

In the above-described substrate for a power module, the entire substrate main body is improved in anisotropy of heat conductivity. Therefore, the substrate main body can be handled similar to a substrate main body constituted with an isotropic material.

In a third aspect of the substrate for a power module of the present invention, the metal matrix composite plate has anisotropy so that heat conductivity in one direction is higher than the heat conductivity in the other direction. The higher-heat conductivity direction of the substrate main body is oriented to a direction which is orthogonal to the thickness direction of the substrate main body.

In the above-described substrate for a power module, even when the substrate main body is not made greater in thickness, heat can be spread sufficiently in the plate-surface direction of the substrate main body.

In the substrate for a power module of the present invention, it is acceptable that a thermal expansion coefficient of the substrate main body is 8×10⁻⁶/° C. or less.

In the above-described substrate for a power module, the thermal expansion coefficient of the substrate main body is made approximate to thermal expansion coefficients of Si and others which constitute the semiconductor device. Therefore, it is possible to reliably suppress the occurrence of cracks in the soldering layer and also to greatly improve the reliability of the substrate for a power module.

In the substrate for a power module of the present invention, it is acceptable that the heat conductivity of the metal matrix composite plate in the higher-heat conductivity direction is 400 W/m·K or more, and the heat conductivity in a direction orthogonal to the higher-heat conductivity direction is 200 W/m·K or more.

In the above-described substrate for a power module, it is possible to dissipate heat generated from the semiconductor device preferentially in the higher-heat conductivity direction. Further, the heat is transmitted in a direction other than the higher-heat conductivity direction, thus making it possible to efficiently dissipate the heat generated from the semiconductor device.

In the substrate for a power module of the present invention, it is acceptable that the metal matrix composite is an aluminum matrix composite in which aluminum or an aluminum alloy is filled into the carbonaceous material.

In the above-described substrate for a power module, aluminum or an aluminum alloy is relatively low in melting point. Therefore, it is possible to easily fill the aluminum or the aluminum alloy into the carbonaceous material. Further, in the higher-heat conductivity direction, heat conductivity is 400 to 450 W/m·K and a thermal expansion coefficient at room temperature up to 200° C. is 6 to 8×10⁻⁶/° C., while in a direction orthogonal to the higher-heat conductivity direction, heat conductivity is 200 to 250 W/m·K and a thermal expansion coefficient at room temperature up to 200° C. is 2 to 4×10⁻⁶/° C. Therefore, it is possible to suppress the occurrence of cracks in a soldered layer due to a difference in thermal expansion coefficient between the substrate for a power module and the semiconductor device and also to dissipate heat efficiently.

In the substrate for a power module of the present invention, it is acceptable that the metal matrix composite is a copper-based composite material in which copper or a copper alloy is filled into the carbonaceous material.

In the above-described substrate for a power module, heat conductivity is 500 to 650 W/m·K and a thermal expansion coefficient at room temperature up to 200° C. is 5 to 7×10⁻⁶/° C. It is, thus, possible to suppress the occurrence of cracks in a soldered layer due to a difference in thermal expansion coefficient between the substrate for a power module and the semiconductor device and also to dissipate heat efficiently.

In the substrate for a power module of the present invention, it is acceptable that a metal skin layer is formed on the first surface of the substrate main body, the metal skin layer being composed of the metal which is filled into the carbonaceous material in the metal matrix composite.

In the above-described substrate for a power module, on one surface of the substrate main body, a metal skin layer composed of metal which is filled into the carbonaceous material of the metal matrix composite is formed. Therefore, it is possible to reliably mount the semiconductor device via a soldered layer. Further, Ni plating or the like is given to the metal skin layer, thus making it possible to improve adhesion with a soldering material.

The power module of the present invention comprises the above-described substrate for a power module, and a semiconductor device to be mounted on the first surface of the substrate main body of the substrate for a power module.

In the above-described power module, it is possible to spread heat generated from the semiconductor device on the substrate main body and efficiently dissipate the heat to the heat sink. Further, even when thermal cycle is imparted, no cracks will occur on a soldered layer. It is, thus, possible to greatly improve the reliability of the power module.

### Advantageous Effects of the Invention

According to the present invention, it is possible to provide a substrate for a power module which is capable of efficiently dissipating heat generated from a semiconductor device and also suppressing the occurrence of cracks in a soldered layer set between the substrate for a power module and the semiconductor device even when thermal cycle is imparted and also to provide a power module which uses the substrate for a power module.

### BRIEF DESCRIPTION OF THE DRAWINGS

FIG. 1 is a view which briefly describes a substrate for a power module and a power module of a first embodiment of the present invention.

FIG. 2 is a cross sectional view, when viewed along arrows A-A in FIG. 1.

FIG. 3 is a cross sectional view which describes the substrate for a power module which is an embodiment of the present invention.

FIG. 4 is a flow chart of a method for producing the power module shown in FIG. 1 and FIG. 2.

FIG. 5 is a view which describes a method for producing a substrate main body.

FIG. 6 is a cross sectional view which describes a substrate for a power module and a power module of a second embodiment of the present invention.

FIG. 7 is a perspective view which shows the substrate main body provided on the substrate for a power module shown in FIG. 6.

FIG. 8 is a cross sectional view which describes the substrate main body shown in FIG. 7.

FIG. 9 is a view which describes a method for producing the substrate main body shown in FIG. 7.

FIG. 10 is a view which describes a heat transmission state of a first metal matrix composite plate installed on the substrate main body in FIG. 7.

FIG. 11 is a view which describes a heat transmission state of a second metal matrix composite plate installed on the substrate main body in FIG. 7.

FIG. 12 is a view which describes a heat transmission state of a third metal matrix composite plate installed on the substrate main body in FIG. 7.

FIG. 13 is a view which briefly describes a substrate for a power module and a power module of a third embodiment of the present invention.

FIG. 14 is a cross sectional view, when viewed along arrows A-A shown in FIG. 13.

FIG. 15 is a cross sectional view which describes a substrate main body installed on the substrate for a power module in FIG. 13.

FIG. 16 is a cross sectional view which briefly describes a substrate for a power module and a power module of a fourth embodiment of the present invention.

FIG. 17 is a cross sectional view which describes a circuit layer (substrate main body) of the fourth embodiment of the present invention.

FIG. 18 is a flow chart of a method for producing the power module which is the fourth embodiment of the present invention.

FIG. 19 is a view which describes a method for producing a metal matrix composite plate constituting the circuit layer (substrate main body) of the power module which is the fourth embodiment of the present invention.

FIG. 20 is a view which describes a method for producing the substrate for a power module which is the fourth embodiment of the present invention.

### MODE FOR CARRYING OUT THE INVENTION

Hereinafter, a description will be given of embodiments of the present invention by referring to the attached drawings.

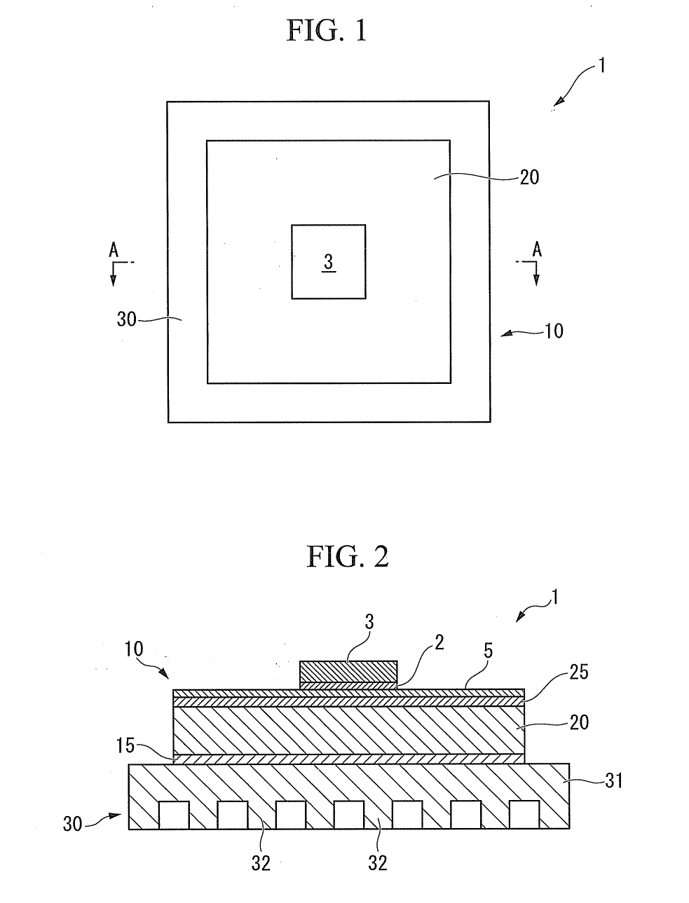

First, a description will be given of the first embodiment of the present invention by referring to FIG. 1 to FIG. 5.

The power module 1 is provided with a substrate for power module 10, a semiconductor device 3 which is bonded via a soldered layer 2 on one surface of the substrate for power module 10 (upper surface in FIG. 2), and a heat sink 30 which is placed on the other surface of the substrate for power module 10 (lower surface in FIG. 2). Here, the soldered layer 2 is composed of, for example, a Sn—Ag based, a Sn—In based or a Sn—Ag—Cu based soldering material.

The heat sink 30 is to cool the semiconductor device 3 mounted on the substrate for power module 10. As shown in FIG. 2, the heat sink 30 is provided with a top plate part 31 which is bonded to the substrate for power module 10 and a radiation fin 32 which is installed vertically from the top plate part 31. The heat sink 30 (top plate part 31) is desirably constituted with a material excellent in heat conductivity. In the present embodiment, the heat sink 30 is constituted, for example, with A6063 (aluminum alloy).

The substrate for power module 10 is provided with a plate-shaped substrate main body 20. On the other surface of the substrate main body 20, an insulation layer 15 composed of an insulating resin is formed. The heat sink 30 is placed thereon via the insulation layer 15. A resin which constitutes the insulation layer 15 includes, for example, resin materials such as an epoxy resin, a glass epoxy resin and a polyimide resin or those in which oriented filler is mixed with these resin materials.

The substrate main body 20 is constituted with a metal matrix composite in which a metal is filled into a carbonaceous material.

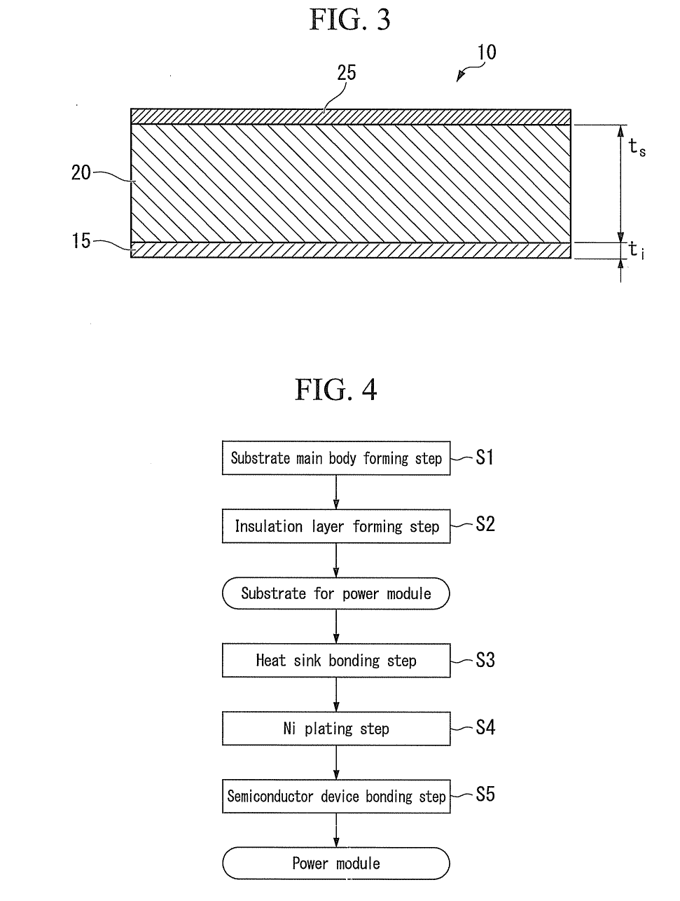

Further, on one surface of the substrate main body 20 (the upper side in FIG. 2 and FIG. 3), a metal skin layer 25 composed of a metal filled into the carbonaceous material is formed. As shown in FIG. 2, a Ni plated layer 5 is formed on the metal skin layer 25. The semiconductor device 3 is mounted on the Ni plated layer 5 via the soldered layer 2.

Here, in the present embodiment, the metal matrix composite which constitutes the substrate main body 20 is constituted with an aluminum-graphite composite material in which aluminum (pure aluminum) with a purity of 99.98% or more is filled into a carbonaceous material whose average spacing d₀₀₂ is 0.340 nm or less. In the metal matrix composite which constitutes the substrate main body 20, 90% by volume or more of pores of the carbonaceous material are replaced by pure aluminum, and the content of the pure aluminum is 35% or less on the basis of a total volume of the aluminum-graphite composite material.

Further, the above-described metal skin layer 25 is constituted with aluminum which is filled into the carbonaceous material.

Here, the above-described carbonaceous material is produced by extrusion processing and constituted so that carbon crystals are arrayed along an extrusion direction thereof. Thereby, in the extrusion direction of the carbonaceous material, aluminum is continuously arranged and consequently increased in heat conductivity. On the other hand, in a direction orthogonal to the extrusion direction, aluminum is separated by the carbonaceous material and decreased in heat conductivity. Therefore, the aluminum-graphite composite material (metal matrix composite) which constitutes the substrate main body 20 has anisotropy so that the heat conductivity of the carbonaceous material in the extrusion direction is made higher than the heat conductivity thereof in the other direction. In addition, the extrusion direction of the carbonaceous material is a higher-heat conductivity direction.

Here, the substrate main body 20 is 8×10⁻⁶/° C. or less in thermal expansion coefficient (from room temperature up to 200° C.). Further, the substrate main body 20 is 400 W/m·K or more in heat conductivity in the higher-heat conductivity direction, more specifically, 400 to 450 W/m·K. The substrate main body 20 is 200 W/m·K or more in heat conductivity in a direction orthogonal to the higher-heat conductivity direction, more specifically, 200 to 250 W/m·K.

A relationship between the thickness is (mm) of the substrate main body 20, the area S (mm²) of the substrate main body 20 and the junction area S₀ (mm²) of the semiconductor device 3 is 0.003≦ts/(S−S₀)≦0.015.

A ratio ti/ts, which is a ratio of thickness ti of the insulation layer 15 to thickness ts of the substrate main body 20, is 0.01≦ti/ts≦0.30.

Next, a description will be given of a method for producing the power module 1 which is the present embodiment.

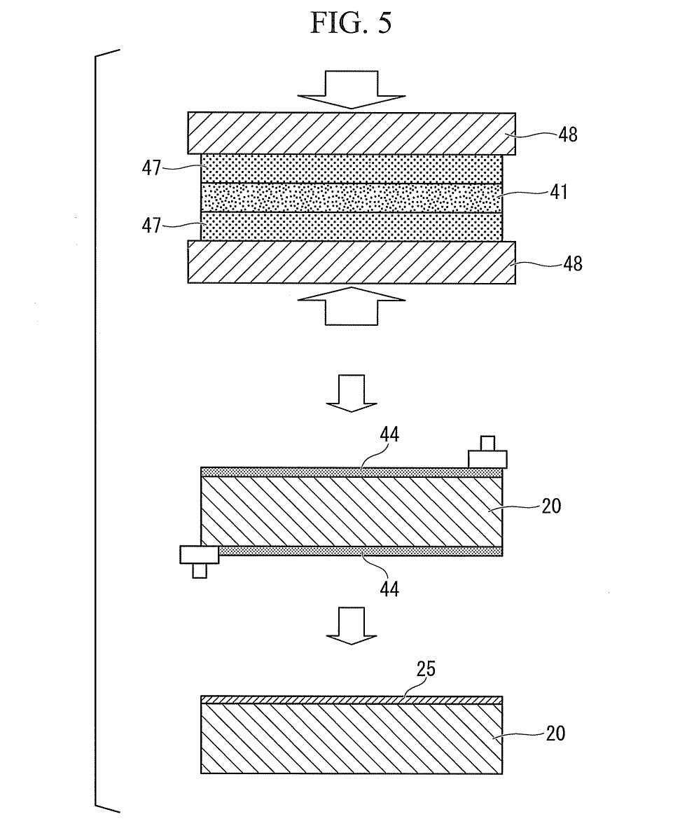

First, the substrate main body 20 which is composed of an aluminum-graphite composite material is formed (substrate main body forming step S1). A description will be given of the substrate main body forming step S1 by referring to FIG. 5. A graphite plate 41 with a porosity of 10 to 30% by volume is prepared. At this time, an extrusion direction of the graphite plate 41 (carbonaceous material) is oriented to the thickness direction. The holding plates 47, 47 composed of graphite with a porosity of 5% by volume or less are placed respectively on both surfaces of the graphite plate 41. These holding plates 47, 47 and the graphite plate 41 are held between pressing plates 48, 48 made of stainless-steel. They are heated at 750° C. to 850° C. while being pressurized at, for example, 100 to 200 MPa. Molten aluminum with a purity of 99.98% or more is impregnated into the graphite plate 41, which is then cooled and coagulated to produce the substrate main body 20 composed of an aluminum-graphite composite material. At this time, the molten aluminum partially oozes out on the surface of the graphite plate 41 (substrate main body 20), thereby forming aluminum layers 44, 44. Each of the aluminum layers 44, 44 is cut to adjust the thickness, by which a metal skin layer 25 is formed.

Next, as shown in FIG. 4, an insulation layer 15 is formed on the other surface of the substrate main body 20 (insulation layer forming step S2). In the insulation layer forming step S2, a resin material such as an epoxy resin, a glass epoxy resin or a polyimide resin may be coated and cured to form the insulation layer 15. Alternatively, a plate material composed of any of these resin materials may be bonded by using an adhesive agent or the like.

As described above, the substrate for power module 10 which is the present embodiment is produced.

Next, the heat sink 30 (top plate part 31) is bonded on the other surface of the substrate for power module 10 (heat sink bonding step S3). In the heat sink bonding step S3, the top plate part 31 of the heat sink 30 is bonded to the insulation layer 15 composed of a resin material by using a bonding material such as an epoxy and adhesive agent.

Further, the Ni plating film 5 is formed on the surface of the metal skin layer 25 formed on one surface of the substrate for power module 10 (Ni plating step S4). In the Ni plating step S4, it is possible to adopt both plating methods, that is, electrolytic plating and non-electrolytic plating.

Then, the semiconductor device 3 is placed via a soldering material on the Ni plating film 5 formed on one surface of the substrate for power module 10, thereby carrying out soldering in a reducing furnace (semiconductor device bonding step S5).

Thereby, the semiconductor device 3 is bonded via the soldered layer 2 on the substrate for power module 10 to produce the power module 1 which is the present embodiment.

In the above-described substrate for power module 10 and the power module 1 of the present embodiment, the substrate main body 20 is constituted with a metal matrix composite in which a metal is filled into a carbonaceous material, more specifically, an aluminum-graphite composite material. Therefore, the substrate main body 20 is 8×10⁻⁶/° C. or less in thermal expansion coefficient which is relatively small, thus making it possible to suppress the occurrence of cracks in the soldered layer 2 due to thermal cycle.

Further, the substrate main body 20 has anisotropy so that heat conductivity in one direction is higher than heat conductivity in the other directions, and the higher-heat conductivity direction of the substrate main body 20 is oriented to the thickness direction of the substrate main body 20. Therefore, it is possible to transmit heat in the thickness direction, even if the thickness of the substrate main body 20 is made thick. Therefore, diffusion of heat can be accelerated in the plate-surface direction by making the substrate main body 20 greater in thickness. It is, thereby, possible to spread and dissipate heat generated from the semiconductor device 3.

Further, the substrate main body 20 is 400 W/m·K or more in heat conductivity in the higher-heat conductivity direction, more specifically, 400 to 450 W/m·K. It is, thus, possible to transmit heat efficiently in the plate thickness direction, even if the thickness of the substrate main body 20 is made thick.

Still further, the substrate main body 20 is 200 W/m·K or more in heat conductivity in a direction orthogonal to the higher-heat conductivity direction, more specifically, 200 to 250 W/m·K. Therefore, it is possible to efficiently diffuse heat in the plate-surface direction by making thick the thickness of the substrate main body 20.

Thus, heat generated from the semiconductor device 3 can be diffused in the plate-surface direction and also transmitted in the plate thickness direction, by which the heat can be efficiently dissipated.

Further, a relational expression between the thickness ts (mm) of the substrate main body 20, the area S (mm²) of the substrate main body 20 and the junction area S₀ (mm²) of the semiconductor device 3, that is, ts/(S−S₀), is 0.003 or more. It is, therefore, possible to secure the thickness ts with respect to the area S of the substrate main body 20 and reliably diffuse heat in the plate-surface direction. Further, since ts/(S−S₀) is 0.015 or less, the thickness of the substrate main body 20 is not made thicker than necessary, and heat can be efficiently transmitted in the thickness direction.

Also, in the present embodiment, a ratio of the thickness ts of the substrate main body 20 and the thickness ti of the insulation layer 15, that is, ti/ts, is 0.01≦ti/ts≦0.30. Therefore, after heat is sufficiently diffused on the substrate main body 20 in the plate-surface direction, the heat can be dissipated via the insulation layer 15 to the heat sink 30.

Further, the metal skin layer 25 is formed on one surface of the substrate main body 20, and the Ni plating film 5 is formed on the metal skin layer 25. It is, therefore, possible to reliably mount the semiconductor device 3 via the soldered layer 2.

As described above, according to the substrate for power module 10 and the power module 1 of the present embodiments, it is possible to efficiently dissipate heat generated from the semiconductor device 3. Further, even where thermal cycle is imparted, it is possible to suppress the occurrence of cracks in the soldered layer 2 set between the substrate for power module 10 and the semiconductor device 3 and also to improve reliability.

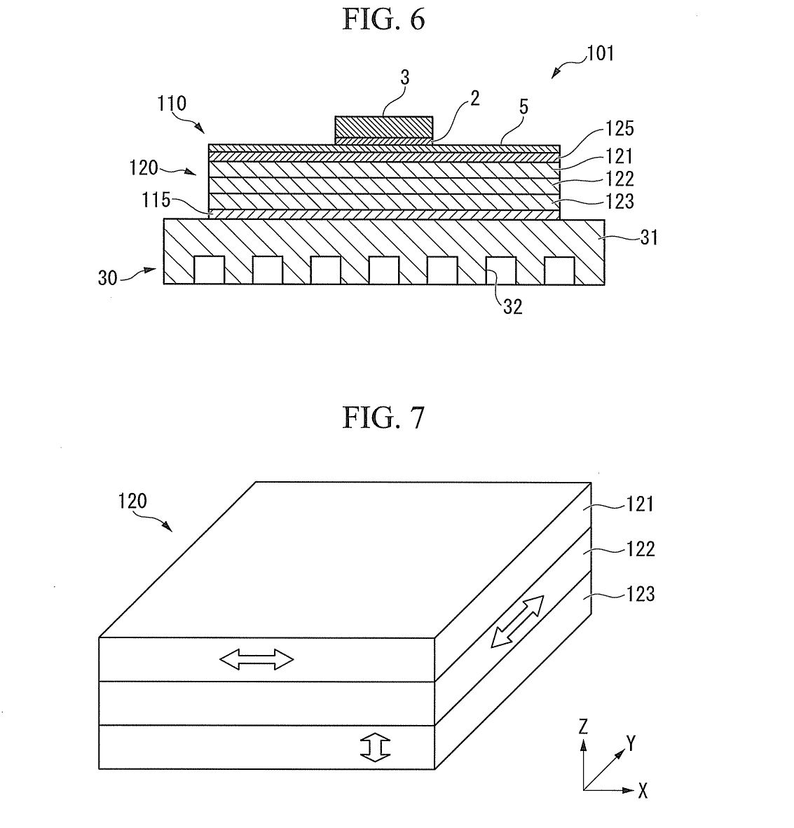

Next, a description will be given of the second embodiment of the present invention by referring to FIG. 6 to FIG. 12. Members which are the same as those of the first embodiment will be given the same symbols, with a detailed description being omitted here.

The substrate for power module 110 is provided with a plate-shaped substrate main body 120. On the other surface of the substrate main body 120, an insulation layer 115 composed of an insulation resin is formed. A heat sink 30 is placed via the insulation layer 115. The present embodiment is different from the first embodiment in constitution of the substrate main body 120.

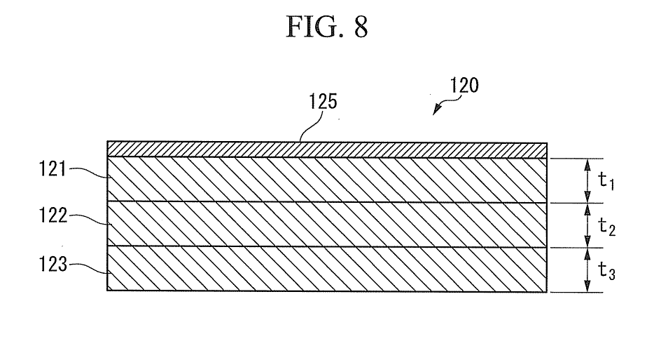

The substrate main body 120 is constituted in such a manner that there are laminated two or more metal matrix composite plates composed of a metal matrix composite in which a metal is filled into a carbonaceous material. In the present embodiment, as shown in FIG. 6, FIG. 7 and FIG. 8, there are laminated three metal matrix composite plates 121, 122, 123, that is, a first metal matrix composite plate 121, a second metal matrix composite plate 122 and a third metal matrix composite plate 123. Further, on one surface of the substrate main body 120 (the upper side in FIG. 6, FIG. 7 and FIG. 8), a metal skin layer 125 is formed. A Ni plated layer 5 is formed on the metal skin layer 125. A semiconductor device 3 is mounted on the Ni plated layer 5 via the soldered layer 2.

In the present embodiment, a metal matrix composite which constitutes the first metal matrix composite plate 121, the second metal matrix composite plate 122 and the third metal matrix composite plate 123 is constituted with an aluminum matrix composite which is similar in constitution to the metal matrix composite of the first embodiment. That is, it is constituted with an aluminum-graphite composite material in which aluminum (pure aluminum) with a purity of 99.98% or more is filled into a carbonaceous material. Further, the above-described metal skin layer 125 is constituted with aluminum filled into a carbonaceous material.

Here, the metal matrix composite which constitutes the first metal matrix composite plate 121, the second metal matrix composite plate 122 and the third metal matrix composite plate 123 has anisotropy so that heat conductivity in the extrusion direction of the carbonaceous material is made higher than heat conductivity in the other direction. The extrusion direction of the carbonaceous material is a higher-heat conductivity direction.

Then, as shown in FIG. 7, the first metal matrix composite plate 121 is arranged so that the high heat conductivity direction is a lateral direction (X direction) in FIG. 7. The second metal matrix composite plate 122 is arranged so that the higher-heat conductivity direction is a left-below to right-above direction (Y direction) in FIG. 7. The third metal matrix composite plate 123 is arranged so that the higher-heat conductivity direction is a vertical direction (Z direction) in FIG. 7. The higher-heat conductivity direction of the first metal matrix composite plate 121, the higher-heat conductivity direction of the second metal matrix composite plate 122 and the higher-heat conductivity direction of the third metal matrix composite plate 123 are arranged so as to be orthogonal to each other.

Further, a plate thickness t1 of the first metal matrix composite plate 121, a plate thickness t2 of the second metal matrix composite plate 122 and a plate thickness t3 of the third metal matrix composite plate 123 are constituted so as to be equal to each other.

Hereinafter, a description will be given of a method for producing the substrate main body 120.

First, a graphite plate (carbonaceous material) with a porosity of 10 to 30% by volume is prepared. At this time, two sheets of the graphite plates (carbonaceous material) are prepared in which the extrusion direction of each graphite plate runs along a plate surface, and two sheets of the graphite plates 141, 142 are laminated so that the extrusion directions thereof are orthogonal to each other. Further, one sheet of the graphite plate, which is formed so that the extrusion direction of the graphite plate (carbonaceous material) is oriented to the plate thickness direction, is prepared, and this graphite plate 143 is laminated under two sheets of the graphite plates 141, 142.

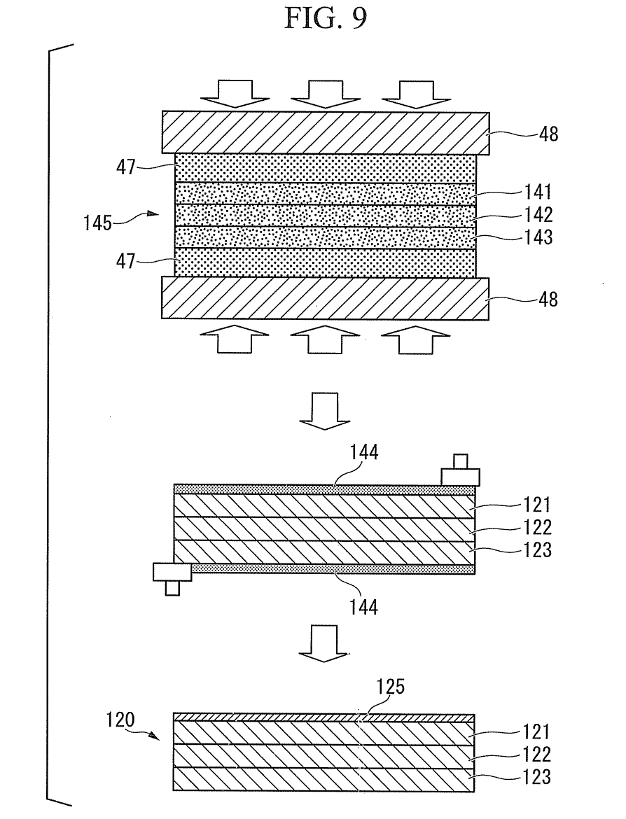

Next, as shown in FIG. 9, the holding plates 47, 47 are placed on both surfaces of a laminated body 145 composed of the graphite plates 141, 142, 143. The holding plates 47, 47 and the laminated body 145 are held between the pressing plates 48, 48. These are subjected to pressurization and heating under the same conditions as those of the first embodiment, by which molten aluminum is impregnated into the graphite plates 141, 142, 143. Then, they are cooled and coagulated to obtain an aluminum matrix composite. Aluminum layers 144, 144 which are formed by oozing out on the surface of the substrate main body 120 are cut and adjusted for thickness, by which a metal skin layer 125 is formed.

Next, a description will be given of actions of the power module 101 and the substrate for power module 110 of the present embodiment.

As shown in FIG. 10, heat generated from the semiconductor device 3 is first spread in a width direction (lateral direction in FIG. 10) by the first metal matrix composite plate 121 arranged on the upper surface of the substrate main body 120.

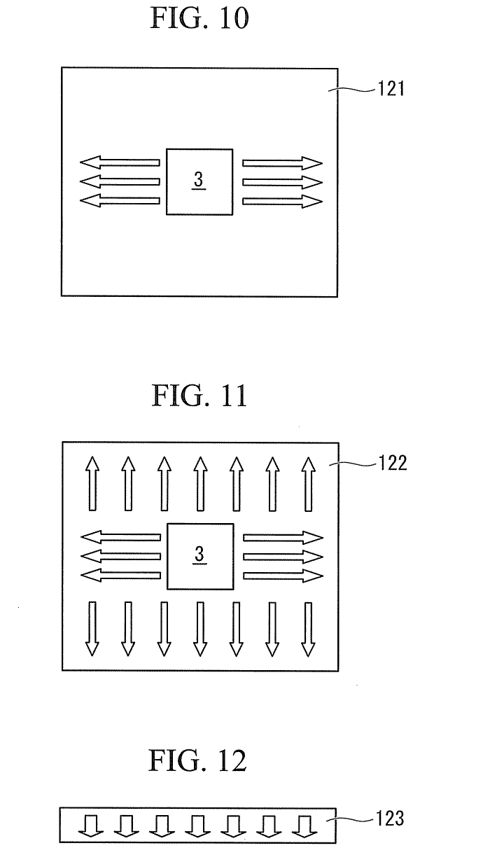

Next, the heat spread in the width direction by the first metal matrix composite plate 121 is spread in a depth direction (vertical direction in FIG. 11) by the second metal matrix composite plate 122 as shown in FIG. 11.

Then, the heat spread by the first metal matrix composite plate 121 and the second metal matrix composite plate 122 entirely on the substrate main body 120 is transmitted in the thickness direction by the third metal matrix composite plate 123, as shown in FIG. 12, and dissipated to the heat sink 30.

In the above-described substrate for power module 110 and the power module 101 of the present embodiment, the substrate main body 120 is that in which three metal matrix composite plates, that is, the first metal matrix composite plate 121, the second metal matrix composite plate 122 and the third metal matrix composite plate 123, are laminated and the higher-heat conductivity direction of the third metal matrix composite plate 123 is oriented to the thickness direction of the substrate main body 120 (direction in which the substrate main body 120 is laminated on the heat sink 30). It is, therefore, possible to dissipate the heat generated from the semiconductor device 3 to the heat sink 30.

Then, the substrate main body 120 is constituted with an aluminum matrix composite. Thereby, heat conductivity in the higher-heat conductivity direction is 400 W/m·K or more, more specifically, 400 to 450 W/m·K and heat conductivity in a direction orthogonal to the higher-heat conductivity direction is 200 W/m·K or more, more specifically, 200 to 250 W/m·K, thus making it possible to efficiently dissipate the heat.

The first metal matrix composite plate 121, the second metal matrix composite plate 122 and the third metal matrix composite plate 123 are arranged in such a manner that their heat conductivity directions are orthogonal to each other. Therefore, as shown in FIG. 10 to FIG. 12, heat generated from the semiconductor device 3 is spread entirely on the substrate main body 120 by the first metal matrix composite plate 121 and the second metal matrix composite plate 122. Thereafter, the heat is dissipated to the heat sink 30 by the third metal matrix composite plate 123. It is, therefore, possible to efficiently dissipate the heat generated from the semiconductor device 3.

Further, in the present embodiment, the first metal matrix composite plate 121, the second metal matrix composite plate 122 and the third metal matrix composite plate 123 are arranged so that their higher-heat conductivity directions are orthogonal to each other and also all made equal in thickness. Therefore, the entire substrate main body 120 is improved in anisotropy of the heat conductivity and shows isotropy. It is, thereby, possible to handle the substrate main body 120 similar to a substrate main body constituted with an isotropic material.

Still further, since the metal skin layer 125 is formed on one surface of the substrate main body 120, the Ni plated layer 5 can be formed on the metal skin layer 125 and the semiconductor device 3 can be mounted via the soldered layer 2. It is, thereby possible to reliably bond the substrate main body 120 to the semiconductor device 3 and greatly improve the reliability of the power module 101.

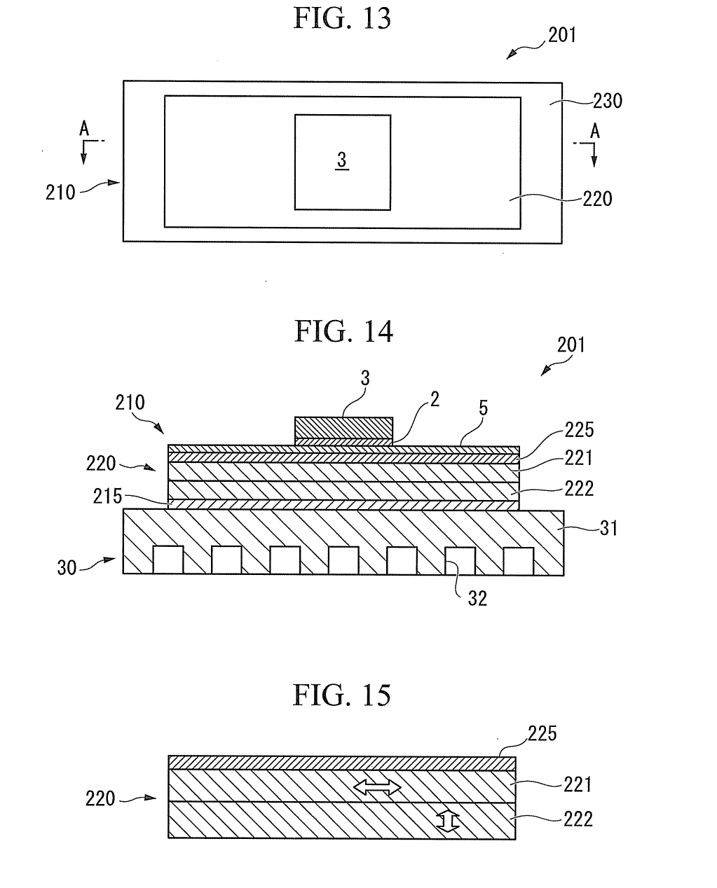

Next, a description will be given of the third embodiment of the present invention by referring to FIG. 13 to FIG. 15. The same members as those of the first and the second embodiments will be given the same symbols, with a detailed description being omitted here.

Each of the power module 201 and the substrate for power module 210 is provided with a plate-shaped substrate main body 220. An insulation layer 215 composed of an insulation resin is formed on the other surface of the substrate main body 220. A heat sink 30 is placed via the insulation layer 215.

The substrate for power module 210 which is the third embodiment is different from the first and the second embodiments in constitution of the substrate main body 220.

In the third embodiment, as shown in FIG. 13, the substrate for power module 210 is not widely spaced in the depth direction (vertical direction in FIG. 13) with respect to the dimensions of the semiconductor device 3 to be mounted, but widely spaced only in the width direction (lateral direction in FIG. 13).

Then, as shown in FIG. 14 and FIG. 15, the substrate main body 220 is constituted so that two metal matrix composite plates, that is, a first metal matrix composite plate 221 and a second metal matrix composite plate 222, are laminated. Further, a metal skin layer 225 is formed on one surface of the substrate main body 220 (the upper side in FIG. 14 and FIG. 15). A Ni plated layer 5 is formed on the metal skin layer 225. On the Ni plated layer 5, a soldered layer 2 is formed and a semiconductor device 3 is mounted thereon.

Here, in the present embodiment, the first metal matrix composite plate 221 and the second metal matrix composite plate 222 are constituted with a metal matrix composite which is an aluminum matrix composite in which aluminum (pure aluminum) with a purity of 99.98% or more is filled into a carbonaceous material, as with the first and the second embodiments.

Further, the above-described metal skin layer 225 is constituted with aluminum filled into the carbonaceous material.

Further, in the present embodiment, as shown in FIG. 15, the first metal matrix composite plate 221 is arranged so that the higher-heat conductivity direction is a lateral direction (X direction) in FIG. 15. The second metal matrix composite plate 222 is arranged so that the higher-heat conductivity direction is a vertical direction (Z direction) in FIG. 15. That is, the first metal matrix composite plate 221 and the second metal matrix composite plate 222 are arranged so that their higher-heat conductivity directions are orthogonal to each other.

Still further, the first metal matrix composite plate 221 and the second metal matrix composite plate 222 are constituted so that the respective plate thicknesses t1 and t2 are equal to each other.

In the above-described substrate for power module 210 and the power module 201 of the third embodiment, heat generated from the semiconductor device 3 is spread by the first metal matrix composite plate 221 in the width direction (lateral direction in FIG. 14 and FIG. 15) and the heat is spread entirely on the substrate main body 220. Then, the heat is dissipated by the second metal matrix composite plate 222 to the heat sink 30.

It is, thereby possible to efficiently dissipate the heat generated from the semiconductor device 3.

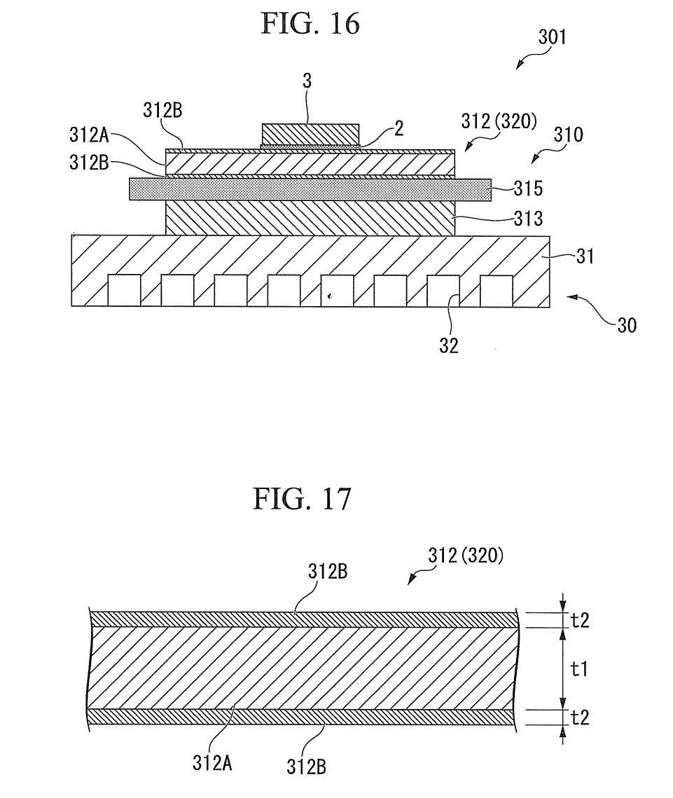

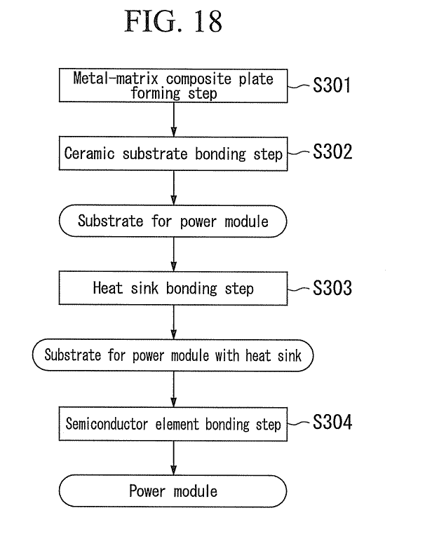

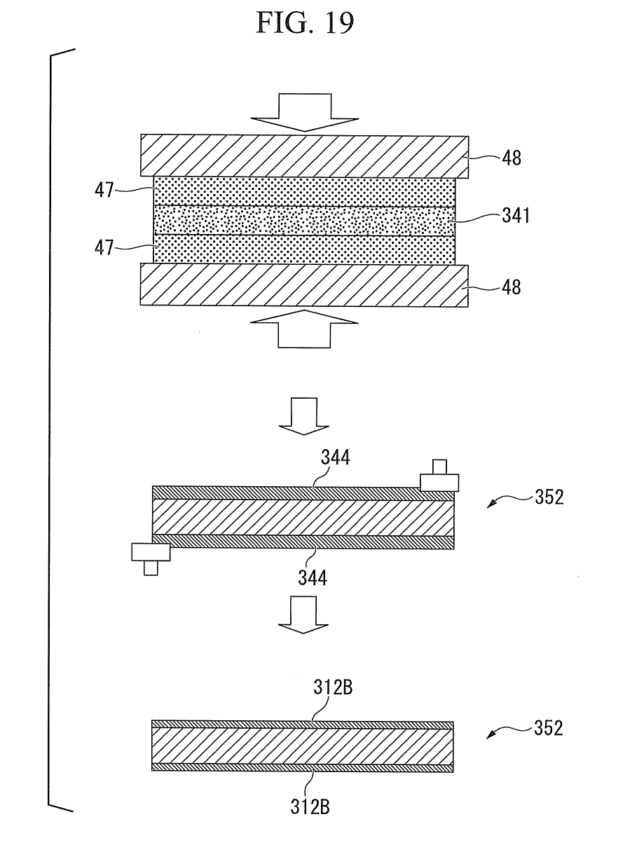

Next, a description will be given of a substrate for power module and a power module of the fourth embodiment of the present invention by referring to FIG. 16 to FIG. 20.

The power module 301 is provided with a substrate for power module 310, a semiconductor device 3 which is bonded via a soldered layer 2 on one surface of the substrate for power module 310 (the upper surface in FIG. 16) and a heat sink 30 placed on the other surface of the substrate for power module 310 (the lower surface in FIG. 16).

The substrate for power module 310 is provided with a ceramic substrate 315, a circuit layer 312 placed on one surface of the ceramic substrate 315, and a buffer layer 313 placed on the other surface of the ceramic substrate 315.

The ceramic substrate 315 is to prevent electric connection between the circuit layer 312 and the buffer layer 313 and constituted with MN (aluminum nitride) high in insulation properties. Further, the ceramic substrate 315 is from 0.2 mm or more to 1.5 mm or less in thickness. In the present embodiment, it is 0.635 mm in thickness.

The buffer layer 313 is formed by bonding a metal plate 353 to the other surface of the ceramic substrate 315. In the present embodiment, the buffer layer 313 is formed by bonding an aluminum plate composed of a rolled plate of aluminum with a purity of 99.99% or more (so-called 4N aluminum) to the ceramic substrate 315. The buffer layer 313 is from 0.2 mm or more to 4.0 mm or less in thickness. In the present embodiment, it is 2.0 mm.

Then, the circuit layer 312 is formed by bonding to one surface of the ceramic substrate 315 a metal matrix composite plate 352 composed of a metal matrix composite in which a metal is filled into a carbonaceous material.

As described above, in the present embodiment, the circuit layer 312 is given as a substrate main body 320, and the ceramic substrate 315 is given as an insulation layer. The metal matrix composite plate 352 which is given as the circuit layer 312 (the substrate main body 320) is in the range of 3.5×10⁻⁶/° C. or more to 15×10⁻⁶/° C. or less in thermal expansion coefficient.

The circuit layer 312 (substrate main body 320) is provided with a main body layer 312A and a metal skin layer 312B formed on one surface and the other surface of the main body layer 312A.

In the present embodiment, the thickness t1 of the main body layer 312A is 0.1 mm≦t1≦3.98 mm, and the thickness t2 of the metal skin layer 312B is 0.01 mm≦t2≦0.5 mm.

Here, in the present embodiment, the metal matrix composite plate 352 which constitutes the circuit layer 312 (substrate main body 320) is constituted with an aluminum matrix composite in which aluminum (pure aluminum) with a purity of 99.98% or more is filled into a carbonaceous material, as with the first to third embodiments. Further, the above-described metal skin layer 312B is constituted with aluminum filled into a carbonaceous material.

Here, the metal matrix composite plate 352 has anisotropy so that the heat conductivity of the carbonaceous material in the extrusion direction is higher than the heat conductivity thereof in the other direction, and the extrusion direction of the carbonaceous material is a higher-heat conductivity direction.

Here, the circuit layer 312 (substrate main body 320) is arranged in such a manner that the higher-heat conductivity direction is oriented to a direction which is orthogonal to the thickness direction of the metal matrix composite plate 352 (a direction in which the ceramic substrate 315 is laminated thereon).

Hereinafter, a description will be given of a method for producing the power module 301 which is the present embodiment. The method for producing the power module 301 is provided with a metal matrix composite plate forming step S301 for forming the metal matrix composite plate 352 which is given as the circuit layer 312 (substrate main body 320), a ceramic substrate bonding step S302 for bonding the metal matrix composite plate 352 to the ceramic substrate 315 to produce the substrate for power module 310, a heat sink bonding step S303 for bonding the substrate for power module 310 to the heat sink 30, and a semiconductor device bonding step S304 for bonding the semiconductor device 3 on one surface of the circuit layer 312 (substrate main body 320).

In the metal matrix composite plate forming step S301, a graphite plate 341 with a porosity of 10 to 30% by volume is prepared. At this time, the graphite plate 341 (carbonaceous material) is that in which the extrusion direction thereof is oriented to a direction orthogonal to the thickness direction. The holding plates 47, 47 are placed on both surfaces of the graphite plate 341, and a laminated body composed of the holding plates 47, 47 and the graphite plate 341 is held between the pressing plates 48, 48. The laminated body is subjected to pressurization and heating under the same conditions as those of the first and the second embodiments, by which molten aluminum is impregnated into the graphite plate 341. Then, the laminated body is cooled and coagulated to obtain an aluminum matrix composite. Aluminum layers 344, 344 formed by oozing out on the surface of the metal matrix composite plate 352 are cut to adjust the thickness, by which a metal skin layer 312B is formed.

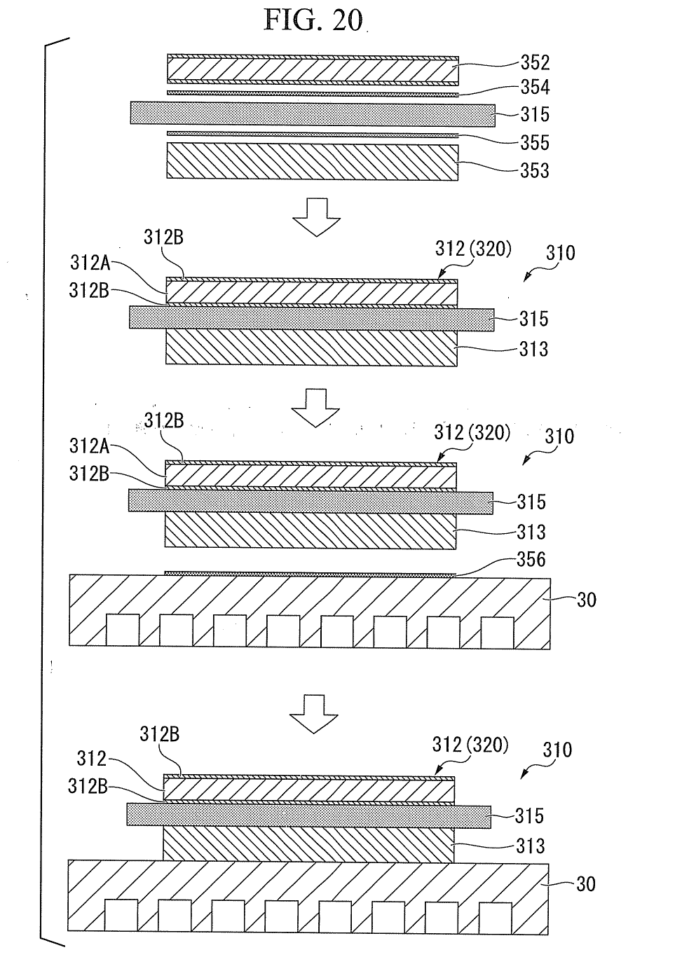

In the ceramic substrate bonding step S302, as shown in FIG. 20, the metal matrix composite plate 352 is laminated on one surface of the ceramic substrate 315 via a brazing material 354, and also the metal plate 353 is laminated on the other surface of the ceramic substrate 315 via a brazing material 355. Here, in the present embodiment, a brazing material foil including Si having Al-7.5% by mass and the thickness of 10 to 12 nm is used as the brazing materials 354, 355.

The metal matrix composite plate 352, the ceramic substrate 315 and the metal plate 353 which have been laminated are set inside a vacuum heating furnace and heated, while they are kept pressurized in the laminated direction (at the pressure of 1.5 to 6.0 kgf/cm²). Thereby, a molten metal region is formed on an interface between the metal matrix composite plate 352 and the ceramic substrate 315, and a molten metal region is formed on an interface between the ceramic substrate 315 and the metal plate 353.

Here, in the present embodiment, a pressure inside the vacuum heating furnace is in the range of 10⁻⁶ Pa or more to 10⁻³ Pa or less, and a heating temperature is in the range of 640° C. to 650° C.

Then, cooling is performed, by which the molten metal region formed on the interface between the metal matrix composite plate 352 and the ceramic substrate 315 is coagulated to bond the metal matrix composite plate 352 to the ceramic substrate 315. The molten metal region formed on the interface between the ceramic substrate 315 and the metal plate 353 is coagulated to bond the ceramic substrate 315 to the metal plate 353.

In the heat sink bonding step S303, as shown in FIG. 20, an Ag paste is coated on a bonded face of the heat sink 30, dried at 150° C. to 200° C. and, thereafter, subjected to burning at 300° C. to 500° C., thereby forming an Ag layer 356. The Ag paste is from approximately 0.02 to 200 μm in thickness after drying. The amount of Ag in the Ag layer 356 is from 0.01 mg/cm² or more to 10 mg/cm² or less.

The Ag paste used here contains Ag powder, a resin, a solvent and a dispersant. The content of the Ag powder is from 60% by mass or more to 90% by mass or less of the total quantity of the Ag paste. Remainders are the resin, the solvent and the dispersant. In the present embodiment, the content of the Ag powder is 85% by mass of the total quantity of the Ag paste.

Further, in the present embodiment, the Ag paste is from 10 Pa·s or more to 500 Pa·s or less in viscosity and, more preferably, from 50 Pa·s or more to 300 Pa·s or less in viscosity.

The Ag powder is from 0.05 μm or more to 1.0 μm or less in grain diameter. In the present embodiment, Ag powder with an average grain diameter of 0.8 μm is used.

A suitable solvent is that having a boiling point of 200° C. or more. For example, α-terpineol, butyl carbitol acetate, diethylene glycol dibutyl ether, and so on, can be favorably used. In the present embodiment, diethylene glycol dibutyl ether is used.

The resin is to adjust the viscosity of the Ag paste and a suitable resin is that which is decomposed at 500° C. or more. For example, an acryl resin and an alkyd resin can be favorably used. In the present embodiment, ethyl cellulose is used.

Further, in the present embodiment, a dicarboxylic acid-based dispersant is added. The Ag paste may be constituted without addition of a dispersant.

Next, the substrate for power module 310 and the heat sink 30 are laminated, set inside the vacuum heating furnace and heated, while pressurized in the laminated direction (at the pressure of 1 to 35 kgf/cm²). Thereby, a molten metal region is formed between the buffer layer 313 of the substrate for power module 310 and the heat sink 30.

This molten metal region is formed due to the fact that Ag of the Ag layer 356 is diffused to the buffer layer 313 and the heat sink 30, by which concentrations of Ag of the buffer layer 313 and the heat sink 30 in the vicinity of the Ag layer 356 are raised to result in a decrease in the melting point.

Where the above-described pressure is less than 1 kgf/cm², the buffer layer 313 of the substrate for power module 310 may not be favorably bonded to the heat sink 30. Further, where the above-described pressure exceeds 35 kgf/cm², the heat sink 30 may be deformed. Thus, it is preferable that the above-described pressure is applied in the range of 1 to 35 kgf/cm².

Here, in the present embodiment, a pressure inside the vacuum heating furnace is in the range of 10⁻⁶ Pa or more to 10⁻³ Pa or less, and a heating temperature is in the range of 600° C. or more to 630° C. or less.

Next, the temperature is kept constant in a state that the molten metal region is formed. Then, Ag of the molten metal region is further diffused to the buffer layer 313 and the heat sink 30. Thereby, concentrations of Ag at a part which was used to be a molten metal region are gradually decreased to increase in melting point, and coagulation progresses, with the temperature kept constant. In other words, the heat sink 30 and the buffer layer 313 are bonded by so-called diffusion bonding (transient liquid phase diffusion bonding).

In the semiconductor device bonding step S304, a Ni film is formed on the surface of the metal skin layer 312B placed on one surface of the circuit layer 312 (substrate main body 320). The semiconductor device 3 is placed on the Ni film via a soldering material and bonded by soldering at the inside of the reducing furnace.

Thereby, the semiconductor device 3 is bonded on the substrate for power module 310 via the soldered layer 2 to produce the power module 301 which is the present embodiment.

According to the above-described substrate for power module 310 and the power module 301 of the present embodiment, the circuit layer 312 (substrate main body 320) to which the semiconductor device 3 is bonded by soldering is given as the metal matrix composite plate 352. Thereby, a thermal expansion coefficient of the circuit layer 312 (substrate main body 320) is made approximate to a thermal expansion coefficient of the semiconductor device 3, thus making it possible to suppress the occurrence of cracks in the soldered layer 2.

Further, a thermal expansion coefficient of the circuit layer 312 is also made approximate to a thermal expansion coefficient of the ceramic substrate 315. Thereby, it is possible to improve the reliability in bonding the ceramic substrate 315 to the circuit layer 312 (substrate main body 320).

In particular, in the present embodiment, as the metal matrix composite plate 352 which constitutes the circuit layer 312 (substrate main body 320), an aluminum-graphite composite material in which aluminum is filled into a carbonaceous material is used and the thermal expansion coefficient is in the range of 3.5×10⁻⁶/° C. or more to 15×10⁻⁶/° C. or less. Therefore, it is possible to reliably prevent occurrence of cracks in the soldered layer 2.

The metal matrix composite plate 352 which constitutes the circuit layer 312 (substrate main body 320) has such a structure that aluminum is filled into a carbonaceous material, thereby securing conductivity. As a result, the metal matrix composite plate 352 can be electrically connected with the semiconductor device 3 via the soldered layer 2.

Further, the metal skin layer 312B is formed on one surface of the circuit layer 312 (substrate main body 320). Therefore, the Ni film is formed on the surface of the metal skin layer 312B, by which the semiconductor device 3 can be favorably bonded via the soldered layer 2. Still further, in the present embodiment, since the metal skin layer 312B is formed also on the other surface of the circuit layer 312 (substrate main body 320), the metal skin layer 312B can be favorably bonded to the ceramic substrate 315.

In the present embodiment, the metal skin layer 312B is set to be in the range of 10 μm or more to 500 μm or less in thickness. It is, therefore, possible to reliably improve the reliability in bonding the circuit layer 312 (substrate main body 320) to the semiconductor device 3 and also to suppress an increase in heat resistance. It is also possible to prevent the metal skin layer 312B from being separated from the main body layer 312A.

Still further, in the present embodiment, the circuit layer 312 (substrate main body 320) is arranged in such a manner that the higher-heat conductivity direction of the metal matrix composite plate 352 is oriented to a direction orthogonal to the thickness direction. It is, therefore, possible to spread heat generated from the semiconductor device 3 in the plate-surface direction and to efficiently dissipate the heat.

In addition, in the present embodiment, the buffer layer 313 composed of 4N aluminum is installed on the other surface of the ceramic substrate 315. It is, therefore, possible to absorb thermal stress resulting from a difference in thermal expansion coefficient between the ceramic substrate 315 and the heat sink 30 and also to improve the reliability of the power module 301.

A description has been so far given of the embodiments of the present invention, to which the present invention shall not be limited. The present invention can be appropriately modified within a scope not departing from the technical idea of the invention.

For example, the first to third embodiments have been described by referring to the insulation layer constituted with a resin, to which the present invention shall not be limited. As shown in the fourth embodiment, the insulation layer may be constituted with ceramics.

The metal matrix composite has been described as an aluminum-graphite composite material in which aluminum is filled into a carbonaceous material, to which the present invention shall not be limited. The metal matrix composite may be that in which other metals, for example, an aluminum alloy, copper and a copper alloy may be filled.

The first to third embodiments have been described by referring to a case where a metal skin layer is formed on one surface of the substrate main body, to which the present invention shall not be limited. The metal skin layer may be formed on the other surface of the substrate main body. For example, where a resin material is bonded via a metal skin layer composed of Al, alumite treatment (aluminum surface treatment) is given to the surface of the metal skin layer, by which the substrate main body can be bonded to a resin material in an improved strength.

Further, a description has been given of a case where as a carbonaceous material, a graphite plate (graphite material) is used, to which the present invention shall not be limited. Silicon carbide (SiC), diamond and others may be used to constitute the carbonaceous material.

Still further, a description has been given of a case where aluminum filled into the metal matrix composite plate is allowed to ooze out to form a metal skin layer, to which the present invention shall not be limited. In forming the substrate main body, a plate material such as aluminum or an aluminum alloy may be held between the holding plates to form the metal skin layer.

Further, a description has been given of a case where a heat sink (top plate part) is constituted with A6063 (aluminum alloy), to which the present invention shall not be limited. The heat sink may be constituted with a different metal such as aluminum or an aluminum alloy. Still further, a description has been given of a heat sink having a fin as the above heat sink. There is no particular limitation on a structure of the heat sink.

Further, in the second and the third embodiments, a description has been given of a case where three or two metal matrix composite plates are laminated to constitute the substrate main body, to which the present invention shall not be limited. The present invention may be that in which four or more metal matrix composite plates are laminated to constitute the substrate main body.

Still further, a description has been given of a constitution in which the laminated metal matrix composite plates are individually made equal in thickness, to which the present invention shall not be limited. Such a constitution is also acceptable that one metal matrix composite plate is different in thickness individually from the other metal matrix composite plates. In this case, heat is more easily spread in the higher-heat conductivity direction of a metal matrix composite plate which is formed to be thicker. Thus, it is possible to adjust anisotropy of the heat conductivity of the substrate main body by controlling the thickness of each of the laminated metal matrix composite plates.

In the fourth embodiment, a description has been given of a case where the ceramic substrate composed of MN is used, to which the present invention shall not be limited. Other ceramic materials such as Si₃N₄ and Al₂O₃ may be used.

In the fourth embodiment, a description has been given of a constitution in which the metal matrix composite plate is bonded to the ceramic substrate by brazing using an Al—Si based brazing material, to which the present invention shall not be limited. A brazing material other than the Al—Si based brazing material may be used. It is acceptable that one or two or more types of elements selected from Cu, Ag, Si, Zn, Mg, Ge, Ca, Ga and Li are used to perform liquid-phase diffusion bonding. It is also acceptable that the metal matrix composite plate is bonded to the ceramic substrate via an Ag sintered layer prepared by burning an Ag paste which contains Ag powder.

Further, in the fourth embodiment, a description has been given of a constitution in which the substrate for power module is bonded to the heat sink by liquid-phase diffusion bonding using Ag, to which the present invention shall not be limited. It is acceptable that one or two or more types of elements selected from Cu, Ag, Si, Zn, Mg, Ge, Ca, Ga and Li are used to perform liquid-phase diffusion bonding. Still further, bonding may be performed via a brazing material. It is also acceptable that the metal matrix composite plate is bonded to the ceramic substrate via an Ag sintered layer prepared by burning an Ag paste which contains Ag powder. Bonding may be performed via a soldering material.

### EXAMPLES

Next, a description will be given of results of confirmation experiments which have been carried out for confirming the effects of the present invention.

### Example 1

A graphite member produced by extrusion method was cut so that the extrusion direction was in the plate thickness to prepare graphite plates. Each of the graphite plates was set inside a mold and subjected to high pressure after pure molten aluminum or pure molten copper was poured, by which a metal matrix composite plate (aluminum-graphite composite material or copper-graphite composite material) was produced. Further, a SiC plate was prepared and subjected to high pressure after pure molten aluminum or pure molten copper was poured, by which a metal matrix composite plate (aluminum-SiC composite material or copper-SiC composite material) was produced.

The thus produced aluminum-graphite composite material was measured for heat conductivity by using the laser flash method in a direction parallel to and a direction perpendicular to the plate thickness direction. As a result, the heat conductivity was 422 W/m·K in the plate thickness direction and 241 W/m·K in the perpendicular direction.

The copper-graphite composite material was measured for heat conductivity by using the laser flash method in a direction parallel to and a direction perpendicular to the plate thickness direction. As a result, the heat conductivity was 530 W/m·K in the plate thickness direction and 342 W/m·K in the perpendicular direction.

The aluminum-SiC composite material was measured for heat conductivity by using the laser flash method in a direction parallel to and a direction perpendicular to the plate thickness direction. As a result, the heat conductivity was 180 W/m·K in the plate thickness direction and 178 W/m·K in the perpendicular direction.

The copper-SiC composite material was measured for heat conductivity by using the laser flash method in a direction parallel to and a direction perpendicular to the plate thickness direction. As a result, the heat conductivity was 221 W/m·K in the plate thickness direction and 219 W/m·K in the perpendicular direction.

These metal matrix composite plates were used to assess an average thermal expansion coefficient, heat resistance and cracks in soldering.

An insulation layer was formed on each of the above-described metal matrix composite plates to produce a substrate for power module having the dimensions described in Table 1. Each of the thus produced substrate for power module was measured for a thermal expansion coefficient at RT to 200° C., thereby calculating an average thermal expansion coefficient.

Next, regarding heat resistance Rth, a silicon chip with the dimensions of 10 mm×10 mm was bonded to each of the substrates for power module shown in Table 1 via a soldering material composed of Sn—Ag—Cu. The silicon chip was allowed to generate heat for measuring a temperature, and the upper surface of the substrate main body and the lower surface of the insulation layer were calculated for heat resistance by referring to the formula shown below.

Rth=(Tj−Ta)/Q

Where

Tj is a temperature of the silicon chip,

Ta is a temperature on the lower surface of the insulation layer,

Q (W) is a heating value of the semiconductor chip.

Regarding the cracks in soldering, after each of the above-described substrates for power module was subjected to temperature cycles (−40° C. to 125° C.×3000 times) (coolant), a lower soldered part of the silicon chip was observed for the cross section to assess development of the cracks (∘: length of crack developed from end is 0.5 mm or less, Δ: length of crack developed from end exceeds more than 0.5 mm, with no practical problem found)

Table 1 shows the results of assessment.

TABLE 1

| | | Substrate for power module | | | | | | | | Assessment | | |
|---|---|---|---|---|---|---|---|---|---|---|---|---|
| | | Material of | Length | | | | | | | Thermal | | |
| | | substrate | of one | | Thickness | Thickness | | | Material of | expansion | Heat | |
| | | main | side | Area S | ts | ti | | | insulation | coefficient × | resistance | Cracks in |
| | | body | (mm) | (mm²) | (mm) | (mm) | ts/(S − S₀) | ti/ts | layer | 10⁻⁶/° C. | ° C./W | soldering |
| Examples | 1 | Al—Gr | 18.0 | 324 | 3.0 | 0.2 | 0.013 | 0.067 | Alumina | 8.39 | 0.053 | ∘ |
| of the | 2 | Al—Gr | 25.0 | 625 | 3.0 | 0.2 | 0.006 | 0.067 | Alumina | 8.39 | 0.030 | ∘ |
| present | 3 | Al—Gr | 30.0 | 900 | 2.5 | 0.2 | 0.003 | 0.080 | Alumina | 8.46 | 0.034 | ∘ |
| invention | 4 | Al—Gr | 40.0 | 1600 | 5.0 | 0.2 | 0.003 | 0.040 | Alumina | 8.16 | 0.021 | ∘ |
| | 5 | Al—Gr | 25.0 | 625 | 3.0 | 0.2 | 0.006 | 0.067 | Resin | 11.13 | 0.047 | Δ |
| | 6 | Al—SiC | 25.0 | 625 | 3.0 | 0.2 | 0.006 | 0.067 | Alumina | 7.58 | 0.083 | ∘ |
| | 7 | Cu—Gr | 25.0 | 625 | 3.0 | 0.2 | 0.006 | 0.067 | Alumina | 8.42 | 0.033 | ∘ |
| | 8 | Cu—Gr | 25.0 | 625 | 3.0 | 0.2 | 0.006 | 0.067 | Resin | 10.57 | 0.053 | Δ |
| | 9 | Cu—SiC | 25.0 | 625 | 3.0 | 0.2 | 0.006 | 0.067 | Alumina | 7.09 | 0.066 | ∘ |
| | 10 | Al—Gr | 12.0 | 144 | 3.0 | 0.2 | 0.068 | 0.067 | Alumina | 8.39 | 0.119 | ∘ |
| | 11 | Al—SiC | 25.0 | 625 | 0.5 | 0.2 | 0.001 | 0.400 | Alumina | 7.89 | 0.093 | ∘ |
| | 12 | Cu—Gr | 12.0 | 144 | 3.0 | 0.2 | 0.068 | 0.067 | Resin | 10.57 | 0.179 | Δ |

As shown in Table 1, it has been confirmed that the substrate main body is smaller in thermal expansion coefficient than copper and aluminum. It has been also confirmed that the substrate main body is relatively small in heat resistance and able to efficiently transmit heat.

In particular, in the examples 1 to 9 of the present invention in which a relationship between the thickness is (mm) of the substrate main body, the area S (mm²) of the substrate main body and the junction area S₀ (mm²) of the semiconductor device is in the range of 0.003≦ts/(S−S₀)≦0.015, the heat resistance is greatly decreased.

### Example 2

A graphite member produced by extrusion method was cut to prepare a graphite plate in which the extrusion direction is oriented to the thickness direction and a graphite plate in which the extrusion direction is oriented to a direction orthogonal to the thickness direction.

These graphite plates were prepared respectively in a plural number and laminated in such a manner that an extrusion direction of each of the graphite plates was orthogonal to each other. A laminated body of the graphite plates was set in a mold and subjected to high pressure after pure molten aluminum or pure molten copper was poured, by which a metal matrix composite plate (aluminum-graphite composite or copper-graphite composite) was produced. Therefore, as shown in Table 2, there were produced substrate main bodies, each of which was composed of a plurality of metal matrix composite plates in which higher-heat conductivity directions are arranged. In addition, X, Y, Z directions in Table 3 are the same as those shown in FIG. 7.

These substrate main bodies were used to assess an average thermal expansion coefficient, heat resistance and cracks in soldering.

The average thermal expansion coefficient was calculated by measuring each of the substrate main bodies with the dimensions of 50 mm×50 mm at RT to 200° C.

The heat resistance Rth was assessed by the following procedures. First, there was produced a substrate for power module in which an insulation layer shown in Table 3 was formed on the other surface of the substrate main body. A silicon chip with the dimensions of 10 mm×10 mm was bonded to the substrate for power module via a soldering material composed of Sn—Ag—Cu. The silicon chip was allowed to develop heat for measuring a temperature, and the heat resistance was calculated by similar procedures as those of the examples.

Cracks in soldering were assessed by the same procedures as those of the example 1.

Table 2 shows the assessment results.

TABLE 2

| | | Substrate for power module | | | | | | | | | Assessment | | |
|---|---|---|---|---|---|---|---|---|---|---|---|---|---|
| | | Material of | Higher-heat | | | | | | Thickness of | Thickness of | Thermal | | |
| | | substrate | conductivity | | | Thickness of | | | insulation | insulation | expansion | Heat | |
| | | main | direction | | | plate (mm) | | | layer | layer | coefficient × | resistance | Cracks in |
| | | body | First | Second | Third | First | Second | Third | (mm) | (mm) | 10⁻⁶/° C. | ° C./W | soldering |
| Examples | 101 | Al—Gr | z | x | y | 1.0 | 1.0 | 1.0 | Alumina | 0.2 | 6.38 | 0.081 | ∘ |
| of the | 102 | Al—Gr | z | x | — | 1.0 | 2.0 | — | Alumina | 0.2 | 5.86 | 0.075 | ∘ |
| present | 103 | Al—Gr | x | y | z | 1.0 | 1.0 | 1.0 | Alumina | 0.2 | 3.92 | 0.081 | ∘ |
| invention | 104 | Al—Gr | z | x | y | 0.5 | 1.0 | 1.5 | Alumina | 0.2 | 6.06 | 0.077 | ∘ |
| | 105 | Al—Gr | z | x | y | 1.0 | 1.0 | 1.0 | Resin | 0.2 | 6.38 | 0.110 | ∘ |
| | 106 | Al—Gr | z | y | — | 1.0 | 2.0 | — | Alumina | 0.2 | 4.14 | 0.070 | ∘ |
| | 107 | Cu—Gr | z | x | y | 1.0 | 1.0 | 1.0 | Alumina | 0.2 | 6.88 | 0.069 | ∘ |
| | 108 | Cu—Gr | z | x | y | 0.5 | 1.0 | 1.5 | Alumina | 0.2 | 6.56 | 0.065 | ∘ |
| | 109 | Cu—Gr | z | x | y | 1.0 | 1.0 | 1.0 | Resin | 0.2 | 6.88 | 0.099 | ∘ |

As shown in Table 2, it has been confirmed that the substrate main body is smaller in thermal expansion coefficient than copper and aluminum. Also, it has been confirmed that the substrate main body is relatively small in heat resistance and able to efficiently transmit heat.

### Example 3

A circuit layer was formed on one surface of a ceramic substrate composed of MN, and a buffer layer was formed on the other surface of the ceramic substrate. The ceramic substrate had the dimensions of 50 mm×50 mm×0.635 mm, while the circuit layer and the buffer layer had respectively the dimensions of 47 mm×47 mm×0.6 mm.

As the circuit layer and the buffer layer, a metal plate or a metal matrix composite plate composed of a material shown in Table 3 was used. Further, the circuit layer, the buffer layer and the ceramic substrate were bonded by using Si foil (thickness of 15 μm) having Al-7.5% by mass in vacuum (10⁻⁵ Torr) at 650° C. and under the load of 75 kg.

As the heat sink, an aluminum plate with the dimensions of 60 mm×70 mm×5 mm was prepared, and the heat sink was bonded to the substrate for power module. Bonding the heat sink to the substrate for power module was performed by using Si foil (thickness of 30 μm) having Al-10% by mass in vacuum (10⁻⁵ Torr) at 610° C. and under the load of 100 kg.

A cooler equipped with a channel for allowing a coolant to flow was bonded to the heat sink. A fin which was a corrugated offset fin equal in dimensions to the ceramic substrate (pitch: 3.0 mm, height: 3.2 mm, fin thickness: 0.2 mm, fin length: 1.0 mm, material: A3003) was bonded by vacuum brazing.

A power cycle test and a thermal cycle test were conducted to assess a change in heat resistance on imparting the power cycles and the thermal cycle.

The heat resistance was measured by the following procedures. A heater chip was heated at electricity of 100 W, and a thermocouple was used to actually measure a temperature of the heater chip. Also, a temperature of the coolant (ethylene glycol: water=1:1) which flowed through the heat sink was actually measured. Then, a value obtained by dividing a difference in temperature between the heater chip and the coolant by the electricity was given as heat resistance.

The power cycle was conducted by repeatedly giving to the heater chip two seconds of current conducting time and eight seconds of cooling time under current conducting conditions of 15V and 150 A and the heater chip was changed in temperature from 30° C. to 130° C. After the above power cycle was conducted 100,000 times, heat resistance was measured. Assessment was made for a rate of increase in heat resistance after the power cycle with respect to initial heat resistance.

Fluorinert (made by Sumitomo 3M Limited) was used as a liquid phase in TSB-51 made by ESPEC CORP. to conduct the thermal cycle. After one cycle consisting of −40° C.×5 minutes and 125° C.×5 minutes was performed 2000 times, heat resistance was measured. Assessment was made for a rate of increase in heat resistance after the thermal cycle with respect to initial heat resistance.

Table 3 shows the results of assessment.

TABLE 3

| | | Circuit layer | | | | Buffer layer | | | | | |
|---|---|---|---|---|---|---|---|---|---|---|---|
| | | | | | Thermal | | | | Thermal | | |
| | | | | | expansion | | | | expansion | Assessment | |
| | | | Thickness | Skin layer | coefficient × | | Thickness | Skin layer | coefficient × | Power | Thermal |
| | | Material | (mm) | (μm) | 10⁻⁶/° C. | Material | (mm) | (μm) | 10⁻⁶/° C. | cycle | cycle |
| Examples | 201 | Al—Gr | 0.4 | 6 | 12.0 | 4N—Al | 2.0 | — | 25.0 | 2.5% | 28% |
| of the | 202 | Al—Gr | 0.6 | 50 | 11.0 | 4N—Al | 2.0 | — | 25.0 | 1.0% | 5% |
| present | 203 | Al—Gr | 1.0 | 200 | 7.5 | 4N—Al | 2.0 | — | 25.0 | 3.2% | 3% |
| invention | 204 | Al—Gr | 1.0 | 250 | 6.8 | Al—Gr | 2.0 | 600 | 11.0 | 1.2% | 38% |
| | 205 | Al—Gr | 1.5 | 250 | 4.8 | Al—Gr | 2.0 | 250 | 12.0 | 2.2% | 1.5% |
| | 206 | Al—Gr | 2.0 | 550 | 4.0 | Al—Gr | 2.0 | 300 | 10.0 | 3.4% | 54% |
| | 207 | Al—Gr | 3.0 | 700 | 3.6 | Al—Gr | 3.0 | 400 | 8.0 | 2.5% | 62% |
| Comparative | 201 | 4N—Al | 0.4 | — | 25.0 | 4N—Al | 2.1 | — | 25.0 | 15.0% | 1.5% |
| examples | 202 | 4N—Al | 0.4 | — | 25.0 | 4N—Al | 2.0 | — | 25.0 | 15.0% | 1.3% |
| | 203 | 4N—Al | 0.2 | — | 25.0 | 4N—Al | 1.8 | — | 25.0 | 12.0% | 0.5% |
| | 204 | 4N—Al | 0.4 | — | 25.0 | 4N—Al | 1.5 | — | 25.0 | 16.0% | 1.0% |

In the comparative examples 201 to 204 in which a 4N aluminum plate with a purity of 99.99% by mass or more is used to form a circuit layer, heat resistance after the power cycle has been imparted is confirmed to be high in rate of increase. This is estimated to be due to occurrence of cracks in a soldered layer.

On the other hand, in the examples 201 to 207 of the present invention in which the metal matrix composite plate is used to form a circuit layer, the heat resistance after the power cycle has been imparted is suppressed. This is estimated to be due to the fact that occurrence of cracks in a soldered layer has been suppressed.

Further, in the examples 202, 203, and 205 of the present invention in which a metal skin layer is formed so as to be from 10 μm or more to 500 μm or less in thickness, it has been confirmed that the rate of increase in heat resistance after the thermal cycle is suppressed.

### INDUSTRIAL APPLICABILITY

The present invention is able to efficiently dissipate heat generated from a semiconductor device and also able to suppress the occurrence of cracks in a soldered layer set between a substrate for power module and the semiconductor device when thermal cycle is imparted.

### DESCRIPTION OF SYMBOLS

1, 101, 201, 301: power module
2: soldered layer
3: semiconductor device
10, 110, 210, 310: substrate for power module
15, 115, 215: insulation layer
20, 120, 220, 320: substrate main body
25, 125, 225, 312B: metal skin layer
315: ceramic substrate (insulation layer)

1. A substrate for a power module comprising:
a substrate main body having a plate-shape;
a first surface, which is a surface of the substrate main body and is a mounting surface that a semiconductor device is mounted on; and
a second surface, which is another surface of the substrate main body and an insulation layer is formed thereon;
wherein the substrate main body is made of a metal matrix composite plate composed of a metal matrix composite in which metal is filled into a carbonaceous material.

2. The substrate for a power module according to claim 1, wherein
the metal matrix composite plate has anisotropy so that heat conductivity in one direction is higher than heat conductivity in the other directions, and
the higher-heat conductivity direction of the substrate main body is oriented to a thickness direction of the substrate main body.

3. The substrate for a power module according to claim 2, wherein
a relationship between thickness is (mm) of the substrate main body, an area S (mm²) of the substrate main body and a junction area S₀ (mm²) of the semiconductor device satisfies a formula, 0.003≦ts/(S−S₀)≦0.015.

4. The substrate for a power module according to claim 1, wherein
the substrate main body is made of a plurality of laminated metal matrix composite plates composed of a metal matrix composite in which metal is filled into the carbonaceous material,
the metal matrix composite has anisotropy so that heat conductivity in one direction is higher than the heat conductivity in the other directions, and
the higher-heat conductivity direction of one of the metal matrix composite plates is different from the higher-heat conductivity direction of the other metal matrix composite plates of the substrate main body.

5. The substrate for a power module according to claim 4, wherein
the higher-heat conductivity direction of the one of the metal matrix composite plates is oriented to the thickness direction of the substrate main body in the substrate main body.

6. The substrate for a power module according to claim 4, wherein
the substrate main body is laminated by three metal matrix composite plates, and
a higher-heat conductivity direction of a first metal matrix composite plate, a higher-heat conductivity direction of a second metal matrix composite plate, and a higher-heat conductivity direction of a third metal matrix composite plate are orthogonal to each other.

7. The substrate for a power module according to claim 6, wherein
the thickness of the first, the second, and the third metal matrix composite plates are the same.

8. The substrate for a power module according to claim 1, wherein
the metal matrix composite plate has anisotropy so that heat conductivity in one direction is higher than the heat conductivity in the other direction, and
the higher-heat conductivity direction of the substrate main body is oriented to a direction which is orthogonal to the thickness direction of the substrate main body.

9. The substrate for a power module according to claim 1, wherein
a thermal expansion coefficient of the substrate main body is 8×10⁻⁶/° C. or less.

10. The substrate for a power module according to claim 1, wherein
the heat conductivity of the metal matrix composite plate in the higher-heat conductivity direction is 400 W/m·K or more, and the heat conductivity in a direction orthogonal to the higher-heat conductivity direction is 200 W/m·K or more.

11. The substrate for a power module according to claim 1, wherein
the metal matrix composite is an aluminum matrix composite in which aluminum or an aluminum alloy is filled into the carbonaceous material.

12. The substrate for a power module according to claim 1, wherein
the metal matrix composite is a copper-based composite material in which copper or a copper alloy is filled into the carbonaceous material.

13. The substrate for a power module according to claim 1, wherein
a metal skin layer is formed on the first surface of the substrate main body, the metal skin layer being composed of the metal which is filled into the carbonaceous material in the metal matrix composite.

14. A power module comprising:
the substrate for a power module according to claim 1; and
a semiconductor device to be mounted on the first surface of the substrate main body of the substrate for a power module.

15. The substrate for a power module according to claim 5, wherein
the substrate main body is laminated by three metal matrix composite plates, and
a higher-heat conductivity direction of a first metal matrix composite plate, a higher-heat conductivity direction of a second metal matrix composite plate, and a higher-heat conductivity direction of a third metal matrix composite plate are orthogonal to each other.

16. The substrate for a power module according to claim 15, wherein
the thickness of the first, the second, and the third metal matrix composite plates are the same.
